(19) United States
(12) Patent Application Publication
(10) Pub. No.: US 2011/0049512 A1
(43) Pub. Date: Mar. 3, 2011

(54) METHOD FOR DEVELOPING THIN FILM FROM OXIDE OR SILICATE OF HAFNIUM NITRIDE, COORDINATION COMPOUND USED IN SAID METHOD, AND METHOD FOR PRODUCING INTEGRATED ELECTRONIC CIRCUIT

(76) Inventors: Stéphane Daniele, Meyzieu (FR); Mohamad Eleter, Villeurbanne (FR); Catherine Dubourdieu, Grenoble (FR); Virginie Brize, Saint Martin d'Heres (FR)

(21) Appl. No.: 12/922,828

(22) PCT Filed: Mar. 16, 2009
(86) PCT No.: PCT/FR2009/000272

§ 371 Date: Nov. 11, 2010

(30) Foreign Application Priority Data
Mar. 17, 2008 (FR) 0801445

(51) Int. Cl. C23C 16/18; H01L 21/324; C07F 7/00; H01L 29/26

(52) U.S. Cl. 257/43; 438/104; 427/248.1; 556/32; 257/E21.497; 257/E29.08

(57) ABSTRACT

The invention provides a method for developing a thin film from oxide or silicate of hafnium nitride, and also provides asymmetric guanidinate coordinate compounds. The invention furthermore provides a method for producing an electronic circuit that includes a step for developing a thin film from oxide or silicate of hafnium nitride through the method of the invention. The method for developing a thin film from hafnium nitride oxide or hafnium nitride silicate according to the invention involves generating the gas phase by heating at least one coordinate compound from the following formula (I): Hf(NR₁R₂)₄₋ₓ[R₃—N═C(NR₁R₂)—NR₄]ₓ wherein R₁ and R₂ are the same or different and selected from a straight or branched, saturated or unsaturated alkyl group in C₁ through C₁₂ and from a saturated or unsaturated cyclic group in C₃ through C₁₂; R₃ and R₄ are different and selected from a straight or branched, saturated or unsaturated alkyl group in C₁ through C₁₂ and from a saturated or unsaturated cyclic group in C₃ through C₁₂ or a group from the Si(R₅)₃ formula wherein R₅ is a straight alkyl group in C₁ through C₆; and x is an integer between 1 and 4 inclusive; then decomposing this gas phase on a heated substrate. The invention is used particularly in the field of microelectronics.

The invention provides a method for producing a thin film of nitrided hafnium oxide or nitrided hafnium silicate from coordination compounds of the guanidinate type with asymmetric ligands. It also relates to a method for producing an integrated electronic circuit comprising a step of producing a thin film of silicate oxide or nitrided hafnium silicate by the method of the invention.

In the current trend toward miniaturization of electronic devices, films of hafnium oxide or hafnium silicate are being intensively studied with a view to replacing SiO₂ films, in particular for producing the oxide for grids of CMOS transistors and the oxide for MIM and DRAM capacitors for example.

The use of thin layers of a hafnium oxide, of stoichiometric formula HfO₂, or of a hafnium silicate of formula HfSiₓO_{y} in the production of integrated electronic circuits is known, notably for preparing portions of material with a high dielectric permittivity value. However, this high value of the dielectric permittivity depends on the crystallographic structure of hafnium oxide. In its monoclinic phase, hafnium oxide has a relative dielectric permittivity ∈ᵣ of the order of 16 to less than 20, while this value lies between 25 and 80 when hafnium oxide possesses a cubic, tetragonal or orthorhombic structure. In order to stabilize these highest symmetry structures, the addition of additives has been proposed (for example lanthanides, Y, Sc etc). The films formed are generally nitrided, following deposition, in order to improve their thermal stability and their barrier properties to the diffusion of oxygen and dopants.

For some microelectronic applications, it may be desired to retain an amorphous structure for the oxide layer. In its amorphous form, HfO₂ has a permittivity of the order of approximately 22 to 26. However, when the material is amorphous, it subsequently crystallizes in the monoclinic form when the circuit is heated during production, after the formation of the hafnium oxide portion. The relative dielectric permittivity of the hafnium oxide portion then again becomes less than approximately 20.

Many methods exist for depositing films on a substrate. Among all these methods, chemical vapor deposition of an organometallic or coordination compound (MOCVD) and deposition of atomic layers (ALD) are particularly suitable for depositing thin films for microelectronic applications.

In the ALD method, each source compound is vaporized and introduced separately from each of the other compounds, and alternately, in the deposition chamber.

A step of purging with an inert gas or of applying a vacuum precedes and follows each introduction of the vapor of each source compound.

A monoatomic layer of the compound forms at each injection of the particular compound in gaseous form, by a chemical reaction at the exposed surface of the substrate.

In the MOCVD method, compounds in vapor form are introduced together or separately into the deposition chamber where one or more chemical reactions take place so as to form a film on the exposed surface of the substrate.

Compounds commonly used up to now for obtaining films of hafnium oxide or silicate are hafnium alkoxides and amides, such as compounds of formula Hf(NR₁R₂)₄ in which R₁ and R₂ may be identical or different and are generally alkyl groups.

The object of the invention is to overcome the disadvantages of the precursors used in methods of the prior art for preparing films of hafnium oxide or silicate by chemical means by proposing the use for these deposits of special hafnium precursors having a guanidinate structure with asymmetric ligands:
that enable thin films to be obtained, of the order of a few nanometers thick, of nitrided hafnium oxide or silicate without a nitriding step after the film is deposited,
that enable films to be obtained in which the HfO₂ phase has a mainly non-monoclinic crystalline structure,
that enable films to be obtained in which the nitrided hafnium silicate phase is amorphous,
that enable films to be obtained in which the HfO₂ phase has a crystallization point above 475° C.

The invention will be better understood and other advantages and features thereof will become more clearly apparent on reading the following explanatory description.

In what follows and has preceded, the terms “non-monoclinic phase” or “non-monoclinic” designate an HfO₂ phase with a crystalline structure with a symmetry higher than the monoclinic phase, namely made with an orthorhombic or quadratic cubic structure.

Within the meaning of the invention, the terms “film with a mainly non-monoclinic crystalline structure” or “film with a mainly non-monoclinic structure” is understood to mean, in the invention, that the film with a crystalline structure concerned contains at least 50% by volume, based on the total volume of the crystalline structures present, of a non-monoclinic crystalline structure.

Within the meaning of the invention, a “thin layer or film” is understood to mean a layer of material that has two substantially parallel faces separated by a layer thickness less than 100 nm. Obtaining the hafnium-based oxide material in the form of such a thin layer is particularly suited to the production of an integrated electronic circuit that has a structure in layers superimposed on a substrate.

The invention provides a method for preparing, by a chemical vapor phase method, a thin film of amorphous nitrided hafnium oxide or in which the hafnium oxide phase has a mainly non-monoclinic crystalline structure or a thin film of amorphous nitrided hafnium silicate, which consists of generating a gaseous phase by evaporating at least one coordination compound, dissolved in a solvent, with the following formula 1:

Hf(NR₁R₂)₄₋ₓ[R₃—N═C(NR₁R₂)—NR₄]ₓ

in which:
R₁ and R₂ are identical or different and are chosen from a saturated or unsaturated linear or branched alkyl group with C₁ to C₁₂, and a saturated or unsaturated cyclic group with C₃ to C₁₂,
R₃ and R₄ are different and are chosen from a saturated or unsaturated linear or branched alkyl group with C₁ to C₁₂, a saturated or unsaturated cyclic group with C₃ to C₁₂ or a group of formula Si(R₅)₃ in which R₅ is a linear alkyl group with C₁ to C₆, and
x is an integer between 1 and 4 inclusive, then of decomposing this gaseous phase on a heated substrate.

Preferably, in the compound of formula 1, the groups R₁ and R₂ are identical or different and chosen from a methyl group or an ethyl group, groups R₃ and R₄ are chosen from an ethyl group, an isopropyl group, a tertiobutyl group and an SiMe₃ group and x is equal to 1 or 2.

Preferably, in this method, the gaseous phase is generated by heating at least one coordination compound of formula 1 dissolved in octane as a solvent, to a temperature between 160° C. and 220° C. and this gaseous phase is decomposed on a substrate heated to a temperature between 300° C. and 600° C. inclusive.

It will clearly appear to a person skilled in the art that any other solvent of the hydrocarbon type may also be used.

Temperatures to which the substrate is heated that are above 600° C. could be used but without supplementary advantages being obtained.

Preferably, the pressure used in the deposition method is approximately 1 to 10 Torr (that is 0.13 to 1.3 kPa).

Of course, in order to obtain a thin film of nitrided hafnium oxide, the coordination compound should be a compound of formula 1 in which neither R₃ nor R₄ have the formula Si(R₅)₃ and in order to obtain a thin film of nitrided hafnium silicate the coordination compound should be a compound of formula 1 in which either R₃ or R₄ has the formula Si(R₅)₃.

Moreover, in order to obtain a nitrided amorphous thin film of HfO₂, the temperature of the substrate is preferably between 300° C. and 475° C. inclusive.

In point of fact, in contrast to films obtained with hafnium precursors of the prior art, films obtained with the coordination compounds of formula 1 crystallize at a temperature above 475° C., which enables them to preserve an amorphous structure during subsequent thermal treatments which would take place at a temperature below or equal to 475° C., in particular of devices in which they are integrated.

On the other hand, in order to obtain a thin nitrided film of hafnium oxide having a mainly non-monoclinic structure, the temperature of the substrate is preferably greater than 475° C. and less than or equal to 600° C.

Here again, temperatures higher than 600° C. may be used but do not bring any advantage.

In all cases, the gaseous phase is generated by heating the compound of formula 1 to a temperature between 160° C. and 220° C. inclusive.

Obtaining a thin film with a nitrided amorphous structure or a mainly non-monoclinic structure in a single deposition step, that is to say not involving a subsequent nitriding step, and maintaining an amorphous structure, when desired, up to 475° C., is therefore particularly advantageous.

The method for obtaining a thin film of nitrided hafnium oxide or of nitrided hafnium silicate of the invention makes it possible to eliminate a supplementary nitriding step, since it enables these films to be nitrided in situ, which makes it possible to gain time and reagents. Moreover, obtaining a non-monoclinic HfO₂ phase with a higher permittivity than the monoclinic HfO₂ phase normally obtained, presents advantages for producing MOS transistors or MIM capacitive structures if the silica thickness is considered that is equivalent electronically to the actual thickness of the layer of nitrided hafnium oxide or of nitrided hafnium silicate.

This equivalent thickness, which is denoted by EOT for “Equivalent Electric Oxide Thickness”, is equal to:

$$EOT = \frac{{ɛ}_{r} ( {SiO}_{2} )}{{ɛ}_{r}} \times e$$

where ∈ᵣ and e denote respectively the relative dielectric permittivity and actual thickness of the thin layer of nitrided hafnium oxide or nitrided hafnium silicate and ∈ᵣ(SiO₂) denotes the relative dielectric permittivity of silica. Normally, ∈ᵣ(SiO₂) is equal to approximately 3.9.

Thus, increasing permittivity enables a smaller EOT to be attained while preserving sufficient film thickness so that the leakage currents remain within acceptable limits for the application.

Moreover, the films obtained, when amorphous, have increased thermal stability up to a temperature of approximately 475° C.

Deposition of nitrided hafnium oxide or nitrided hafnium silicate from at least one coordination compound of the invention may be, as will be clearly apparent to a person skilled in the art, carried out by an MOCVD method with or without pulsed injection, as well as by an ALD method.

The films obtained in the invention have a thickness of between 0.9 and 30 nm.

The invention also relates to coordination compounds enabling thin films of nitrided hafnium silicate to be obtained by the method of the invention.

These compounds have the following formula 1a:

Hf(NR₁R₂)₄₋ₓ[R₃—N═C(NR₁R₂)—NR₄]ₓ

in which R₁, R₂, R₃, R₄ and x are as defined for the compounds of formula 1 but in which either R₃ or R₄ has the formula Si(R₅)₃ and preferably either R₃ or R₄ is SiMe₃.

The invention also provides a method for producing an electronic circuit that comprises a portion of a thin film layer based on nitrided hafnium oxide or nitrided hafnium silicate.

According to the invention, the method comprises a step of producing a film of nitrided hafnium oxide or nitrided hafnium silicate by the method of the invention previously described.

The invention also provides an electronic circuit that comprises a portion of a layer of film of nitrided hafnium-based oxide or nitrided hafnium silicate produced by the method of the invention.

In order to understand the invention better, several embodiments will now be described by way of purely illustrative and non-limiting examples.

### EXAMPLE 1

The coordination compound, of formula

Hf[N(CH₂CH₃)₂]₃{(CH₃)₂CH—N═C[N(CH₂CH₃)₂]—NC(CH₃)₃}

was diluted with octane to a concentration of 0.05 M.

The thin film of nitrided hafnium oxide was formed by the pulsed injection MOCVD method. A volume of 0.60 ml of the solution of the above coordination compound, diluted with octane, was injected.

The injection frequency was 1 Hz with an opening time of 1 ms. The injector was pressurized to a pressure of 1 bar of argon. The coordination compound was vaporized at a temperature of 160° C. and then decomposed on an Si/SiO₂ substrate with a thickness of 0.8 nm heated to 350° C. using a flow of 100 sccm of nitrogen and 200 sccm of oxygen at a total pressure of 0.13 kPa.

The nitrided hafnium oxide film obtained was amorphous and was 12.6 nm thick.

The same results were obtained when the temperature for vaporizing the coordination compound was increased to 180° C. and to 205° C. respectively.

### EXAMPLE 2

The procedure was as in example 1, except that the substrate was heated to a temperature of 375° C. and that a volume of 0.58 ml of the solution of the coordination compound, diluted in octane, was injected.

The film obtained was amorphous and was 4.9 nm thick.

### EXAMPLE 3

The procedure was as in example 1, except that the substrate was heated to a temperature of 400° C. In this example, a volume of 0.60 ml of the solution of the coordination compound, diluted in octane, was injected.

The film obtained was amorphous and was 2.9 nm thick.

### EXAMPLE 4

The procedure was as in example 1, except that the substrate was heated to a temperature of 450° C. The volume injected of the solution of the coordination compound, diluted in octane, was 0.60 ml.

The film obtained was amorphous and was 4.1 nm thick.

### EXAMPLE 5

The procedure was as in example 1, except that the substrate was heated to a temperature of 475° C. The volume injected of the solution of the coordination compound, diluted in octane, was 0.53 ml.

The film obtained was amorphous and was 1.3 nm thick.

### EXAMPLE 6

The procedure was as in example 1, except that the substrate was heated to a temperature of 530° C. and that the volume injected of the solution of the coordination compound, diluted in octane, was 0.80 ml.

The film obtained consisted of nitrided HfO₂ in which the HfO₂ phase had a mainly non-monoclinic structure. The film obtained was 12.3 nm thick.

### EXAMPLE 7

The procedure was as in example 1, except that the substrate was heated to a temperature of 580° C. and that a volume of 0.86 ml of the solution of the coordination compound diluted in octane was injected.

The film obtained was a 14.7 nm thick film of nitrided hafnium oxide. The HfO₂ phase had a mainly non-monoclinic crystalline structure.

### EXAMPLE 8

The procedure was as in example 6, but using a coordination compound of formula:

Hf[N(CH₃)₂]₂{CH₃CH₂—N═C[N(CH₃)₂]—NC(CH₃)₃}₂.

The volume injected of this coordination compound diluted with octane was 0.40 ml.

The film obtained consisted of nitrided HfO₂ in which the HfO₂ phase had a monoclinic/orthorhombic or monoclinic/quadratic or monoclinic/cubic mixed crystalline structure. The film was 4.1 nm thick.

### EXAMPLE 9

The procedure was as in example 8, except that the substrate was heated to a temperature of 580° C. and that a volume of 0.70 ml of the solution of the coordination compound diluted in octane was injected.

The film obtained was a film of nitrided hafnium oxide in which the HfO₂ phase had a mainly non-monoclinic structure. The film obtained was 24.9 nm thick.

### EXAMPLE 10

The procedure was as in example 1, except that the substrate was heated to a temperature of 475° C. and that the volume injected of the solution of the coordination compound, diluted in octane, was 0.45 ml.

The film obtained was amorphous and was 4.45 nm thick.

### EXAMPLE 11

This example describes the synthesis of a coordination compound used in the invention:

Hf[N(CH₂CH₃)₂]₃{(CH₃)₂CH—N═C[N(CH₂CH₃)₂]—NC(CH₃)₃}.

One equivalent of N,N′ ethyl-terbutylcarbodiimide (280 mg; 2.22 mmol) in 5 ml of toluene was added to a solution of Hf[N(CH₂CH₃)₂]₄ (1.05 g; 2.24 mmol) in 15 ml of toluene. After stirring at room temperature for 18 hours, the solvent was evaporated off under vacuum. After extraction with pentane, Hf[N(CH₂CH₃)₂]₃{(CH₃)₂CH—N═C[N(CH₂CH₃)₂]—NC(CH₃)₃} was obtained in the form of a yellow oil (weight=1.25 g; yield=95%).

NMR¹H (25° C., C₆D₆, ppm): 0.96 (6H, doublet, ³J=7.16 Hz); 1.11 (3H, triplet, ³J=7.00 Hz); 1.16 (18H, triplet, ³J=7.00 Hz); 1.32 (9H, singlet); 2.93 (4H, quadruplet, ³J=7.16 Hz); 3.21 (2H, quadruplet, ³J=7.00 Hz); 3.44 (12H, quadruplet, ³J=7.00 Hz).

1. A method for producing a thin film of amorphous nitrided hafnium oxide or in which hafnium oxide has a mainly non-monoclinic structure or a thin film of amorphous nitrided hafnium silicate, characterized in that it consists of generating a gaseous phase by evaporating at least one coordination compound, dissolved in a solvent, of the following formula 1:
Hf(NR₁R₂)₄₋ₓ[R₃—N═C(NR₁R₂)—NR₄]ₓ
in which:
R₁ and R₂ are identical or different and are chosen from a saturated or unsaturated linear or branched alkyl group with C₁ to C₁₂, and a saturated or unsaturated cyclic group with C₃ to C₁₂,
R₃ and R₄ are different and are chosen from a saturated or unsaturated linear or branched alkyl group with C₁ to C₁₂, a saturated or unsaturated cyclic group with C₃ to C₁₂ and an Si(R₅)₃ group in which R₅ is a linear alkyl group with C₁ to C₆, and
x is an integer between 1 and 4 inclusive,
then of decomposing this gaseous phase on a heated substrate.

2. The method as claimed in claim 1, characterized in that said at least one coordination compound has the formula 1 in which R₁ and R₂ are identical or different from each other and are chosen from a methyl group or an ethyl group, groups R₃ and R₄ are different and are chosen from an ethyl group, an isopropyl group, a tertiobutyl group or an SiMe₃ group and x is equal to 1 or 2.

3. The method for producing a thin film of nitrided hafnium oxide as claimed in claim 1, characterized in that the gaseous phase is generated by heating at least one coordination compound of formula 1 in which R₃ and R₄ are different from Si (R₅)₃, dissolved in octane, to a temperature between 160° C. and 220° C. inclusive, and is then decomposed on a substrate heated to a temperature between 300° C. and 600° C. inclusive.

4. The method for producing a thin film of amorphous nitrided hafnium oxide as claimed in claim 1, characterized in that the gaseous phase is generated by heating at least one coordination compound of formula 1 in which R₃ and R₄ are different from Si(R₅)₃, to a temperature between 160° C. and 220° C. inclusive, and is then decomposed on a substrate heated to a temperature between 350° C. and 475° C. inclusive.

5. The method for producing a thin film of nitrided hafnium oxide in which the hafnium oxide phase has a mainly non-monoclinic structure, as claimed in claim 1, characterized in that the gaseous phase is generated by heating at least one coordination compound having the formula 1 in which R₃ and R₄ are different from Si(R₅)₃, to a temperature between 160° C. and 220° C., and decomposed on a substrate heated to a temperature above 475° C. and less than or equal to 600° C.

6. The method for producing a thin film of nitrided hafnium silicate as claimed in claim 1, characterized in that the gaseous phase is generated by heating at least one compound of formula 1 in which either R₃ or R₄ is a group of formula Si(R₅)₃, to a temperature between 160° C. and 220° C., and decomposed on a substrate heated to a temperature between 350° C. and 600° C. inclusive.

7. A coordination compound having the following formula 1a:
Hf(NR₁R₂)₄₋ₓ[R₃—N═C(NR₁R₂)—NR₄]ₓ
in which:
R₁ and R₂ are identical or different and are chosen from a saturated or unsaturated linear or branched alkyl group with C₁ to C₁₂, and a saturated or unsaturated cyclic group with C₃ to C₁₂,
R₃ and R₄ are different from each other and are chosen from a saturated or unsaturated linear or branched alkyl group with C₁ to C₁₂, a saturated or unsaturated cyclic group with C₃ to C₁₂ and a group of formula Si(R₅)₃ in which R₅ may be a linear alkyl group with C₁ to C₆, either R₃ or R₄ being an Si(R₅)₃ group, and
x is an integer of value between 1 and 4 inclusive.

8. The coordination compound as claimed in claim 7, characterized in that it has the formula 1a in which R₁ and R₂ are identical or different and chosen from a methyl group or an ethyl group, R₃ and R₄ are different from each other and are chosen from an ethyl group, an isopropyl group, a tertiobutyl group or an SiMe₃ group, either R₃ or R₄ being an SiMe₃ group and x is equal to 1 or 2.

9. A method for producing an electronic circuit, characterized in that it comprises a step of producing a film of nitrided hafnium oxide or nitrided hafnium silicate by the method as claimed in claim 1.

10. An electronic circuit, characterized in that it comprises a portion of a thin layer or film based on nitrided hafnium oxide or nitrided hafnium silicate obtained by the method as claimed in claim 1.
